(19) United States
(12) Patent Application Publication
(10) Pub. No.: US 2014/0061572 A1
(43) Pub. Date: Mar. 6, 2014

(54) SEMICONDUCTOR DEVICE AND METHOD OF MANUFACTURING THE SAME

(71) Applicant: SK HYNIX INC., Gyeonggi-do (KR)

(72) Inventor: Heung-Jae CHO, Gyeonggi-do (KR)

(73) Assignee: SK hynix Inc., Gyeonggi-do (KR)

(21) Appl. No.: 13/719,449

(22) Filed: Dec. 19, 2012

(30) Foreign Application Priority Data
Aug. 29, 2012 (KR) 10-2012-0094641

(51) Int. Cl. H01L 21/8239; H01L 27/22; H01L 27/06; H01L 27/24

(52) U.S. Cl. CPC H01L 21/8239; H01L 27/2436; H01L 27/22; H01L 27/0629
USPC 257/4; 257/295; 257/306; 438/238; 438/253

(57) ABSTRACT

This technology relates to a semiconductor device and a method of manufacturing the same. A semiconductor device may include a line layer formed over a substrate, and connection structures each configured to include a first metal layer pattern, a barrier layer pattern, and a second metal layer pattern sequentially stacked over the line layer, for bonding another substrate to the substrate. In accordance with this technology, abnormal silicidation may be prevented because the barrier layer is formed at the bonding interface of the substrates, and the bonding energy of the substrates may be improved by titanium (Ti)-silicon (Si) bonding.

### CROSS-REFERENCE TO RELATED APPLICATIONS

The present application claims priority of Korean Patent Application No. 10-2012-0094641, filed on Aug. 29, 2012, which is incorporated herein by reference in its entirety.

### BACKGROUND

1. Field

Exemplary embodiments of the present invention relate to a semiconductor device and a method for manufacturing the same, and more particularly, to a semiconductor device formed by wafer bonding and a method of manufacturing the same.

2. Description of the Related Art

Wafer bonding technology for increasing the degree of integration of memory devices by bonding a plurality of semiconductor substrates is being developed.

FIGS. 1A to 1C are cross-sectional views illustrating a conventional semiconductor device and a method of manufacturing the same.

Referring to FIG. 1A, a first substrate 10 in which specific underlying structures (not shown) are formed is prepared. The first substrate 10 is an acceptor substrate and can be based on a semiconductor substrate, such as single crystalline silicon (Si).

A line layer that is formed of a plurality of lines 14 and a plurality of contact plugs 16 within an interlayer insulating layer 12 over the first substrate 10 is formed. A first tungsten layer 18 is formed over the first substrate 10 in which the line layer is formed.

Referring to FIG. 1B, after preparing a second substrate 20 to be bonded to the first tungsten layer 18 of the first substrate 10, a second tungsten layer 22 is formed over the second substrate 20. The second substrate 20 is a donor substrate and can be based on a semiconductor substrate, such as single crystalline silicon (Si).

Referring to FIG. 1C, the first substrate 10 and the second substrate 20 are bonded together so that the first tungsten layer 18 and the second tungsten layer 22 couple with each other. Here, in order to increase bonding energy between the first substrate 10 and the second substrate 20, an annealing process may be performed. The conventional technology has the following concerns.

FIG. 2 is a graph showing bonding energy according to annealing temperature (cited from “Electronic Components and Technology Conference, pp. 1359-1363 2010”).

Referring to FIG. 2, in general, there is a tendency that the bonding energy of the substrate is increased according to an increase of post bonding annealing temperature. From FIG. 2, it can be seen that tungsten/tungsten (W/W) bonding has very lower bonding energy than silicon oxide/silicon oxide (SiO₂/SiO₂) bonding.

FIG. 3 is an electron microscope photograph illustrating a conventional semiconductor device.

Referring to FIG. 3, abnormal tungsten silicide (WSiₓ) may be formed by a reaction of a tungsten (W) layer with silicon (Si) due to an annealing process that is performed in conventional wafer bonding. The abnormally formed tungsten silicide (WSiₓ) may become a factor in deteriorating the reliability of wafer bonding.

### SUMMARY

Exemplary embodiments of the present invention is directed to provide a semiconductor device capable of preventing abnormal silicidation by a barrier layer that is formed at the bonding interface of substrates and improving the bonding energy of the substrates through titanium (Ti)-silicon (Si) bonding and a method of manufacturing the same.

In accordance with an embodiment of the present invention, a semiconductor device may include a line layer formed over a substrate, and connection structures each configured to include a first metal layer pattern, a barrier layer pattern, and a second metal layer pattern sequentially stacked over the line layer, for bonding another substrate to the substrate.

In accordance with an embodiment of the present invention, a method for manufacturing a semiconductor device includes forming a line layer over a first substrate, sequentially stacking a first metal layer, a harrier layer, and a second metal layer over the line layer, forming one or more impurity layers over a second substrate, and bonding the first substrate and the second substrate so that the second metal layer and one of the impurity layers face each other,

### BRIEF DESCRIPTION OF THE DRAWINGS

FIGS. 1A to 1C are cross-sectional views illustrating a conventional semiconductor device and a method of manufacturing the same.

FIG. 2 is a graph illustrating bonding energy according to annealing temperature.

FIG. 3 is an electron microscope photograph illustrating a conventional semiconductor device.

FIGS. 4A to 4J are cross-sectional views illustrating a semiconductor device and a method of manufacturing the same in accordance with a first embodiment of the present invention,

FIGS. 5A to 5D are cross-sectional views illustrating semiconductor device and a method of manufacturing the same in accordance with a second embodiment of the present invention.

FIG. 6 is an electron microscope photograph illustrating a semiconductor device in accordance with an embodiment of the present invention.

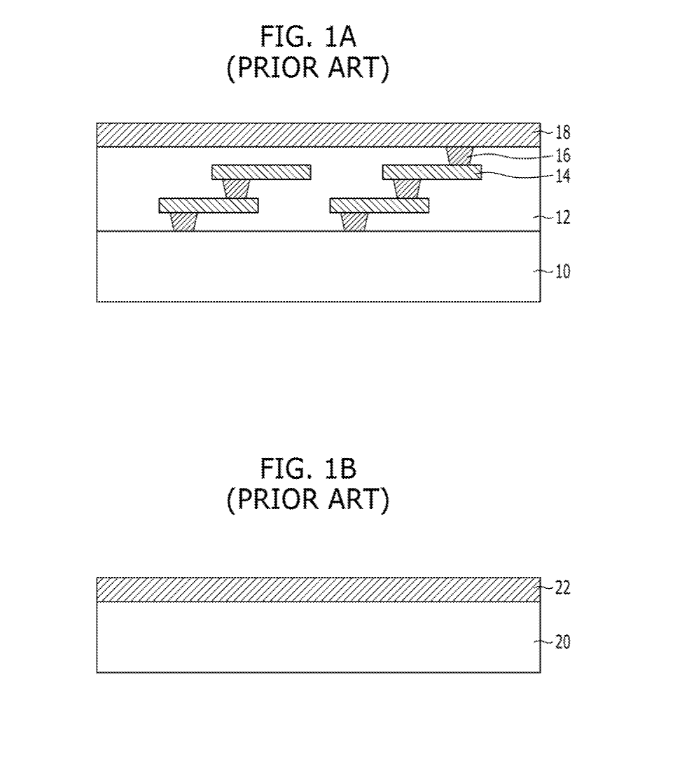

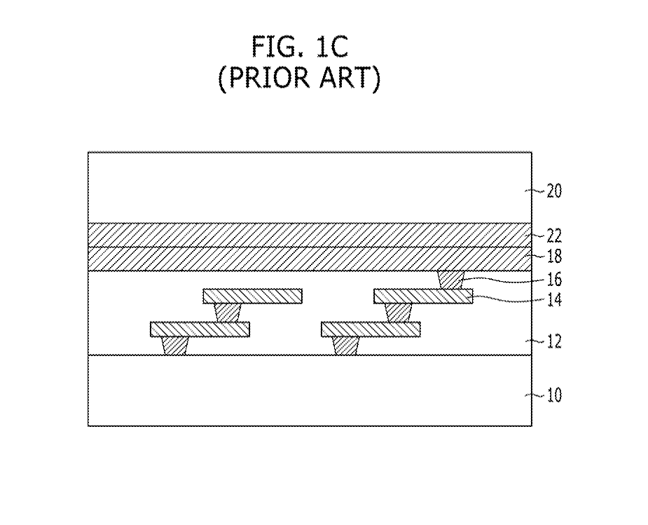

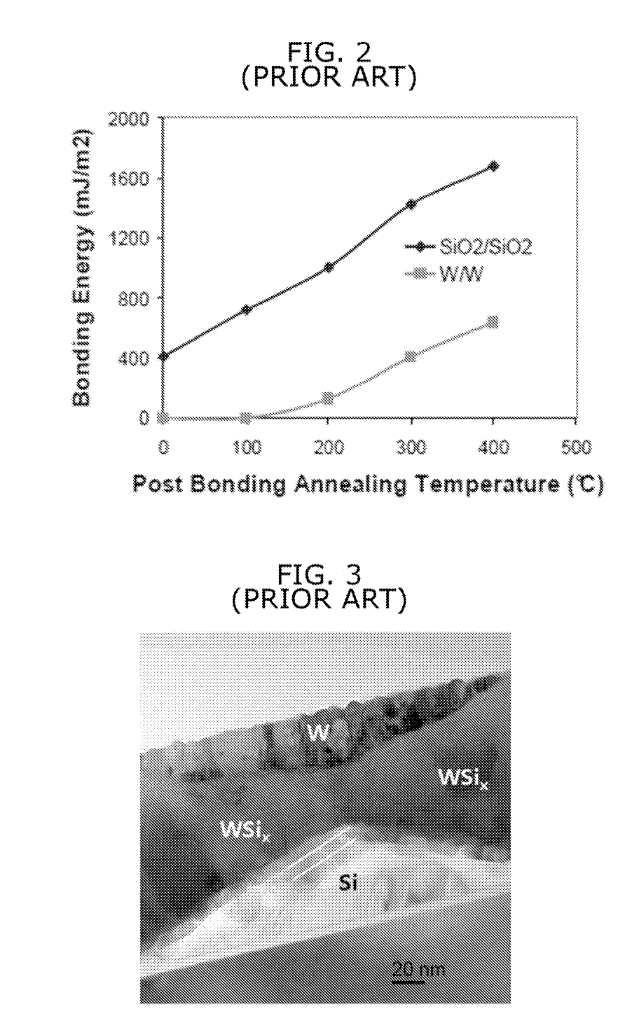

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention. In this specification, ‘connected/coupled’ represents that one component is directly coupled to another component or indirectly coupled through another component. In addition, a singular form may include a plural form as long as it is not specifically mentioned in a sentence.

The drawings are not necessarily to scale and in some instances, proportions may have been exaggerated in order to clearly illustrate features of the embodiments. It should be readily understood that the meaning of “on” and “over” In the present disclosure should be interpreted in the broadest manner such that “on” not only means “directly on” something but also include the meaning of “on” something with an intermediate feature or a layer therebetween, and that “over” not only means the meaning of “over” something may also include the meaning it is “over” something with no intermediate feature or layer therebetween (i.e., directly on something).

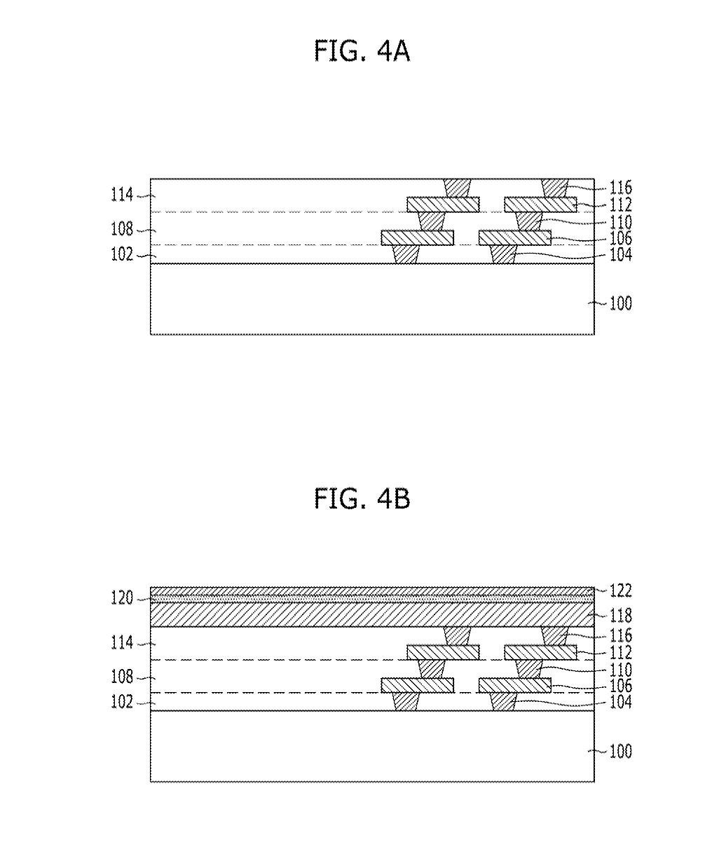

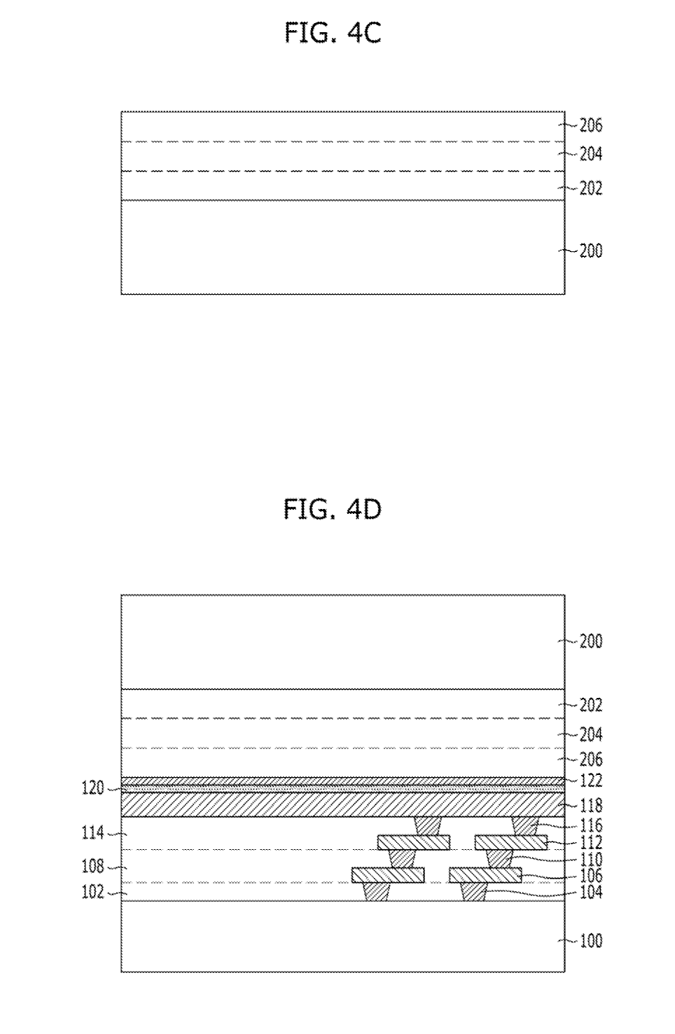

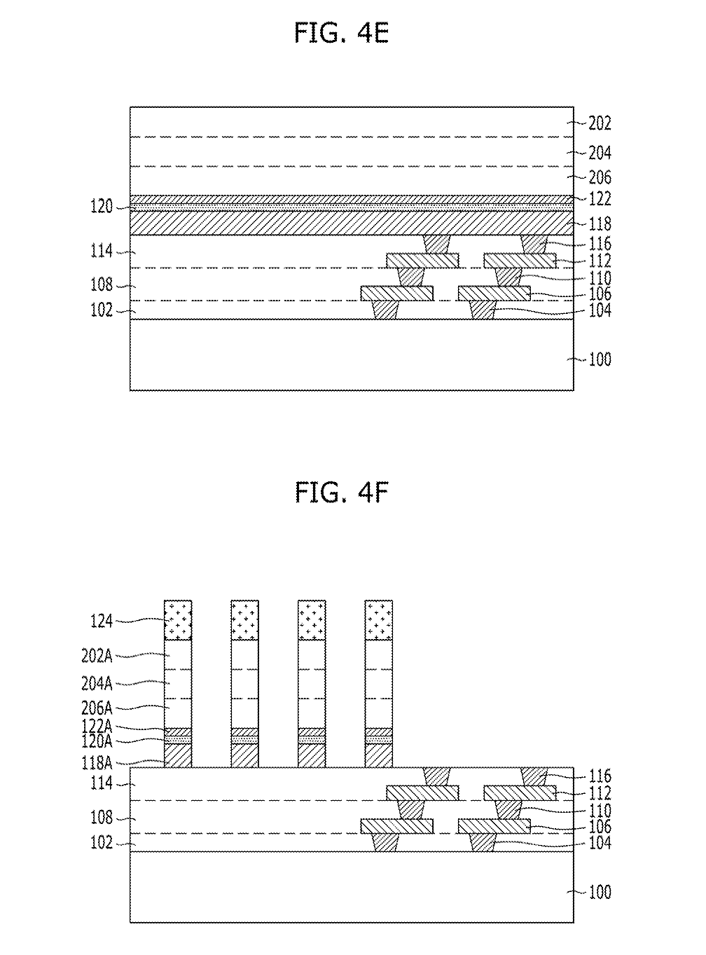

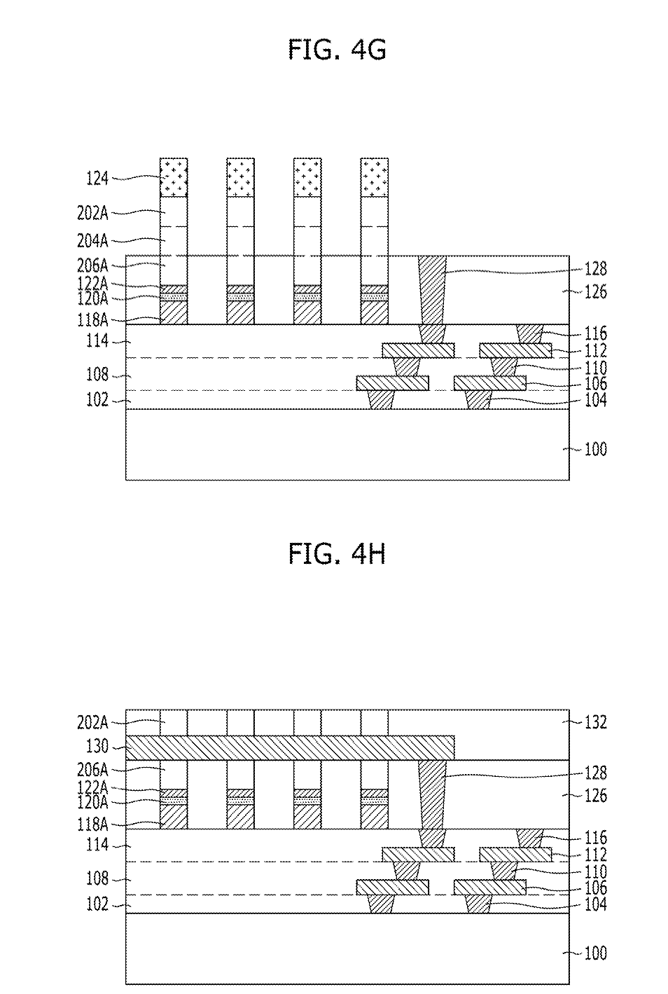

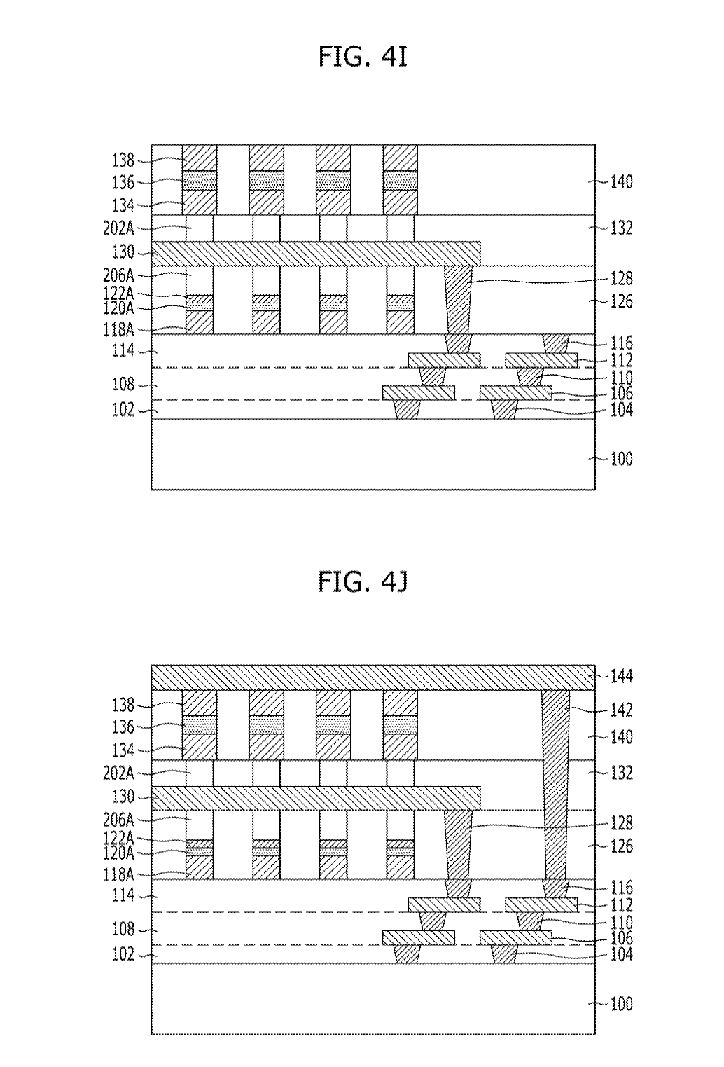

FIGS. 4A to 4J are cross-sectional views illustrating a semiconductor device and a method of manufacturing the same in accordance with a first embodiment of the present invention. Particularly, FIG. 4J is a cross-sectional view illustrating the semiconductor device in accordance with the first embodiment of the present invention, and FIGS. 4A to 4I are cross-sectional views illustrating an example of the intermediate steps of a process for fabricating the semiconductor device of FIG. 4J.

Referring to FIG. 4A, a first substrate 100 in which specific underlying structures (not shown) are formed is prepared. The first substrate 100 may be based on a silicon (Si) substrate, a germanium (Ge) substrate, a silicon germanium (SiGe) substrate, a sapphire substrate, a silicon-on-insulator (SOI) substrate, or a silicon-germanium-on-insulator (SGOI) substrate. Particularly, the first substrate 100 is an acceptor substrate, and it may include a peripheral circuit element for driving the semiconductor device although is not shown in the drawings. The peripheral circuit element is configured to control cell transistors and storage elements to be described later and to generate voltages necessary for the cell transistors and the storage elements.

A multi-layered line layer is formed over the first substrate 100. The line layer may be formed by the following process. First, a first interlayer insulating layer 102 is formed over the first substrate 100. Contact holes (not shown) configured to penetrate the first interlayer insulating layer 102 are formed by selectively etching the first interlayer insulating layer 102. First contact plugs 104 are formed by filling the contact holes with conductive material. First lines 106 connected to the top surfaces of the first contact plugs 104 are formed. The first lines 106 may be formed by a damascene process that is well known to those skilled in the art and may be connected to the peripheral circuit element, formed in the first substrate 100, through the first contact plugs 104.

The first interlayer insulating layer 102 may include one or more oxide layer-series materials, for example, silicon oxide (SiO₂) tetra ethyl ortho silicate (TEOS), boron silicate glass (BSG), phosphorus silicate glass (PSG), fluorinated silicate glass (FSG), boron phosphorus silicate glass (BPSG), or spin on glass (SOG). Furthermore the first contact plugs 104 and the first lines 106 may be formed by depositing conductive material, for example, doped polysilicon metal, or metal nitride.

Likewise, second and third interlayer insulating layers 108 and 114, second and third contact plugs 110 and 116, and second lines 112 may be formed. Meanwhile, in the present embodiment, the first and the second lines 106 and 112, that is, a line layer is illustrated as having the two layers, but the present invention is not limited thereto. For example, the line layer may be formed to have more than or less than two layers.

Referring to FIG. 4B, a first metal layer 118 is formed over the first substrate 100 in which the line layer is formed. The first metal layer 118 may be formed by depositing one or more selected from the group that includes pieces of metal having low resistivity, for example, tungsten (W), copper (Cu), gold (Au), and aluminum (Al).

A barrier layer 120 is formed over the first metal layer 118. The barrier layer 120 is configured to prevent the first metal layer 118 from being abnormally silicided through a reaction with silicon (Si), The barrier layer 120 may include one or more metal nitrides or nitrided metal silicides. For example, the barrier layer 120 may be formed by depositing one or more selected from the group that includes titanium nitride (TiN), tungsten nitride (WN), tantalum nitride (TaN), titanium silicide nitride (TiSiN), tungsten silicide nitride (WSiN), and tantalum silicide nitride (TaSiN) to a thickness of about 50 Å to 500 Å.

A second metal layer 122 is formed over the barrier layer 120. The second metal layer 122 may be formed by depositing metal having high bonding energy with silicon (Si), for example, titanium (Ti), to a thickness of about 20 Å to 500 Å.

Referring to FIG. 4C, a second substrate 200 to be bonded to the second metal layer 122 of the first substrate 100 is prepared. The second substrate 200 is a donor substrate and may be based on a substrate including single crystalline silicon (Si).

A first impurity layer 202, a second impurity layer 204, and a third impurity layer 206 are formed over the second substrate 200. The first to third impurity layers 202 204, and 206 are formed by doping p-type or n-type impurities using an ion implantation process, but layers neighboring each other may be formed to have different conduction types That is, the first and the third impurity layers 202 and 206 may have an n-type and the second impurity layer 204 may have a p-type, thus forming an n/p/n structure, or the first and the third impurity layers 202 and 206 may have a p-type and the second impurity layer 204 may have an n-type, thus forming a p/n/p structure. Meanwhile, although not shown in the drawing, a porous separation layer may be interposed between the second substrate 200 and the first impurity layer 202 so that the first to third impurity layers 202, 204, and 206 may be easily separated from the second substrate 200 in a subsequent process.

Referring to FIG. 4D, the first substrate 100 and the second substrate 200 are bonded together so that the second metal layer 122 and the third impurity layer 206 face each other. Here, bonding energy between the first substrate 100 and the second substrate 200 may be increased by performing an annealing process while applying specific pressure between the second metal layer 122 and the third impurity layer 206.

Referring to FIG. 4E, the second substrate 200 other than the first to third impurity layers 202, 204, and 206 is removed. Here, the second substrate 200 may be removed by performing a grinding, polishing, or etching process until the first impurity layer 202 is exposed.

Referring to FIG. 4F, hard mask patterns 124 are formed on the first impurity layer 202. First to third impurity layer patterns 202A, 204A, and 206A, second metal layer patterns 122A, barrier layer patterns 120A, and first metal layer patterns 118A are formed by etching the first to third impurity layers 202, 204, and 206, the second metal layer 122, the barrier layer 120, and the first metal layer 118 using the hard mask pattern 124 as an etch mask.

The first to third impurity layer patterns 202A, 204A, and 206A, the second metal layer patterns 122A, the barrier layer patterns 120A, and the first metal layer patterns 118A may be formed by the following process. First, the first to third impurity layers 202, 204, and 206, the second metal layer 122, the barrier layer 120, and the first metal layer 118 are etched by using a first hard mask pattern (not shown) of a line form, extending in one direction, as an etch mask. The first to third impurity layers 202, 204, and 206 are etched using a second hard mask pattern (not shown) of a line form, extending in a direction crossing the first hard mask pattern, as an etch mask.

As a result of this process, the first to third impurity layer patterns 202A, 204A, and 206A may be patterned in a pillar form that is substantially perpendicularly protruded from the first substrate 100, and the second metal layer patterns 122A, the barrier layer pattern 120A, and the first metal layer patterns 118A may be patterned in a line form. Meanwhile, the second impurity layer pattern 204A may be used as the channel of a cell transistor for controlling a memory cell, and the first and the third impurity layer patterns 202A and 206A may be used as bonding regions, that is, a source and a drain. Furthermore, a structure in which the first metal layer pattern 118A, the barrier layer pattern 120A, and the second metal layer pattern 122A are sequentially stacked (hereinafter referred to as a ‘connection structure’) may be used as a bit line.

Referring to FIG. 4G, a fourth interlayer insulating layer 126 is formed to fill a space between the structures in each of which the first metal layer pattern 118A, the barrier layer pattern 120A, the second metal layer pattern 122A, and the third impurity layer pattern 206A are sequentially stacked. The fourth interlayer insulating layer 126 may include one or more oxide layer-series materials, for example, silicon oxide (SiO₂), TEOS, BSG, PSG, FSG, BPSG, or SOG.

A fourth contact plug 128, which is configured to penetrate the fourth interlayer insulating layer 126 and connected to the third contact plugs 116, is formed. The fourth contact plug 128 may be formed by selectively etching the fourth interlayer insulating layer 126 in order to form contact holes (not shown) that penetrate the fourth interlayer insulating layer 126 and filling the contact holes with conductive material, such as doped polysilicon, metal, or metal nitride.

Referring to FIG. 4H, a gate insulating layer (not shown) is formed on the sides of the first and the second impurity layer patterns 202A and 204A. The gate electrode 130 of the above-described cell transistor is formed on the sides of the second impurity layer patterns 204A. The gate insulating layer may be a silicon oxide layer formed by a thermal oxidation process, and the gate electrode 130 may be formed by depositing conductive material, such as doped polysilicon, metal, or metal nitride. Meanwhile, the gate electrode 130 may be configured to surround the sides of the second impurity layer patterns in 204A, extended in one direction, and connected to the fourth contact plug 128. The gate electrode 130 may be used as a word line.

Next, a fifth interlayer insulating layer 132 is formed on the space in which the gate electrode 130 is formed. The fifth interlayer insulating layer 132 may be formed by depositing oxide layer-series material to a thickness that fills a space between the first impurity layer patterns 202A and then performing a polishing process, such as chemical mechanical polishing (CMP) until a top surface of the first impurity layer pattern 202A is exposed. Meanwhile, as a result of this process, the hard mask patterns 124 remaining on the first impurity layer patterns 202A may be removed.

Referring to FIG. 4I, storage elements in each of which a lower electrode 134, a variable resistance layer 136, and an upper electrode 138 are sequentially stacked are formed over the first impurity layer patterns 202A. The storage element may have a pillar form that is substantially perpendicularly protruded from the first substrate 100 and may form a memory cell along with the above-described cell transistor.

The lower electrode 134 and the upper electrode 138 may include conductive material, for example, metal nitride, such as titanium nitride (TiN), tantalum nitride (TaN), or tungsten nitride (WN), metal, such as tungsten (W), aluminum (Al), copper (Cu) gold (Au), silver (Ag), platinum (Pt), nickel (Ni), chromium (Cr), cobalt (Co), titanium (Ti), ruthenium (Ru), hafnium (Hf), or zirconium (Zr), or doped polysilicon.

Furthermore, the variable resistance layer 136 may have a structure whose electrical resistance is changed by oxygen vacancies, the migration of ions, or a phase change of material or may have a magnetic tunnel junction (MTJ) structure whose electrical resistance is changed by a magnetic field or spin transfer torque (STT).

The structure whose electrical resistance is changed by oxygen vacancies or the migration of ions may include provskite-series material, such as STO (SrTiO₃), BTO (BaTiO₃), and PCMO (Pr₁₋ₓCaₓMnO₃), or binary oxide including transition metal oxide (TMO), such as titanium oxide (TiO₂), hafnium oxide (HfO₂), zirconium oxide (ZrO₂), aluminum oxide (Al₂O₃), tantalum oxide (Ta₂O₅) niobium oxide (Nb₂O₅), cobalt oxide (Co₃O₄), nickel oxide (NiO), tungsten oxide (WO₃) and lanthan oxide (La₂O₃). The structure whose electrical resistance is changed by a phase change of material may include material that is changed in a crystalline or amorphous state by heat, for example, calcogenide-series material, such as GeSbTe (GST) in which germanium (Ge), antimony (Sb), and tellurium (Te) is mixed in a specific ratio.

Furthermore, the magnetic tunnel junction (MTJ) structure may include a magnetic-free layer, a magnetic fixing layer, and a barrier layer interposed therebetween. The magnetic-free layer and the magnetic fixing layer may include a ferromagnetic substance, for example, iron (Fe), nickel (Ni), cobalt (Co), gadolinium (Gd), dysprosium (Dy), or a compound thereof. The barrier layer may include magnesium oxide (MgO), aluminum oxide (Al₂O₃), hafnium oxide (HfO₂) zirconium oxide (ZrO₂), or silicon oxide (SiO₂).

Next, a sixth interlayer insulating layer 140 is formed on the space in which the storage elements are formed. The sixth interlayer insulating layer 140 may be formed by depositing oxide layer-series material to a thickness that fills a space between the storage elements and then performing a polishing process, such as CMP, until a top surface of the upper electrode 138 is exposed.

Referring to FIG. 4J, a fifth contact plug 142, which is configured to penetrate the fourth to sixth interlayer insulating layers 126, 132, and 140 and connected to the third contact plugs 116, is formed. The fifth contact plug 142 may be formed by selectively etching the fourth to sixth interlayer insulating layers 126, 132, and 140 in order to form a contact hole (not shown) through which the third contact plug 116 not connected to the fourth contact plug 128 is exposed and filling the contact hole with conductive material, such as doped polysilicon, metal or metal nitride.

Next, a third line 144 connected to the upper electrodes 138 is formed. The third line 144 may be formed by depositing conductive material, such as doped polysilicon, metal, or metal nitride. Meanwhile, the third line 144 may be extended in one direction and connected to the fifth contact plug 142. The third line 144 may be connected to the line layer through the fifth contact plug 142.

The semiconductor device in accordance with the first embodiment of the present invention, such as that shown in FIG. 4J, may be fabricated by the above-described manufacture method.

Referring to FIG. 4J, the semiconductor device in accordance with the first embodiment of the present invention may include the line layer formed over the first substrate 100, the connection structures in each of which the first metal layer pattern 118A, the barrier layer pattern 120A, and the second metal layer pattern 122A are sequentially stacked over the line layer, the cell transistors connected to the tops of the connection structures, and the storage elements connected to the top surfaces of the cell transistors.

The line layer may include the first and the second lines 106 and 112, and the barrier layer pattern 120A may include metal nitride or nitrided metal silicide, or a combination thereof. Furthermore, the first metal layer pattern 118A may include one or more selected from the group that includes pieces of metal having low resistivity for example, tungsten (W), copper (Cu), gold (Au), and aluminum (Al). The second metal layer pattern 122A may include metal having high bonding energy with silicon (Si), such as titanium (Ti).

The cell transistor may include the first to third impurity layer patterns 202A, 204A, and 206A substantially perpendicularly protruded from the first substrate 100 and the gate electrode 130 configured to be in contact with the sides of the second impurity layer patterns 204A. The first to third impurity layer patterns 202A, 204A, and 206A may include silicon (Si). Particularly, the second impurity layer pattern 204A is the channel of the cell transistor, and the first and the third impurity layer patterns 202A and 206A may be used as bonding regions, that is, a source and a drain.

Each of the storage elements may include the lower electrode 134 and the upper electrode 138 spaced apart from the lower electrode 134. The variable resistance layer 136 may be interposed between the lower electrode 134 and the upper electrode 138. The variable resistance layer 136 may have the structure whose electrical resistance is changed by oxygen vacancies, the migration of ions, or a phase change of material or may have the magnetic tunnel junction (MTJ) structure whose electrical resistance is changed by a magnetic field or spin transfer torque (STT). Meanwhile, the storage elements may be connected to the line layer through the third line 144 and the fifth contact plug 142.

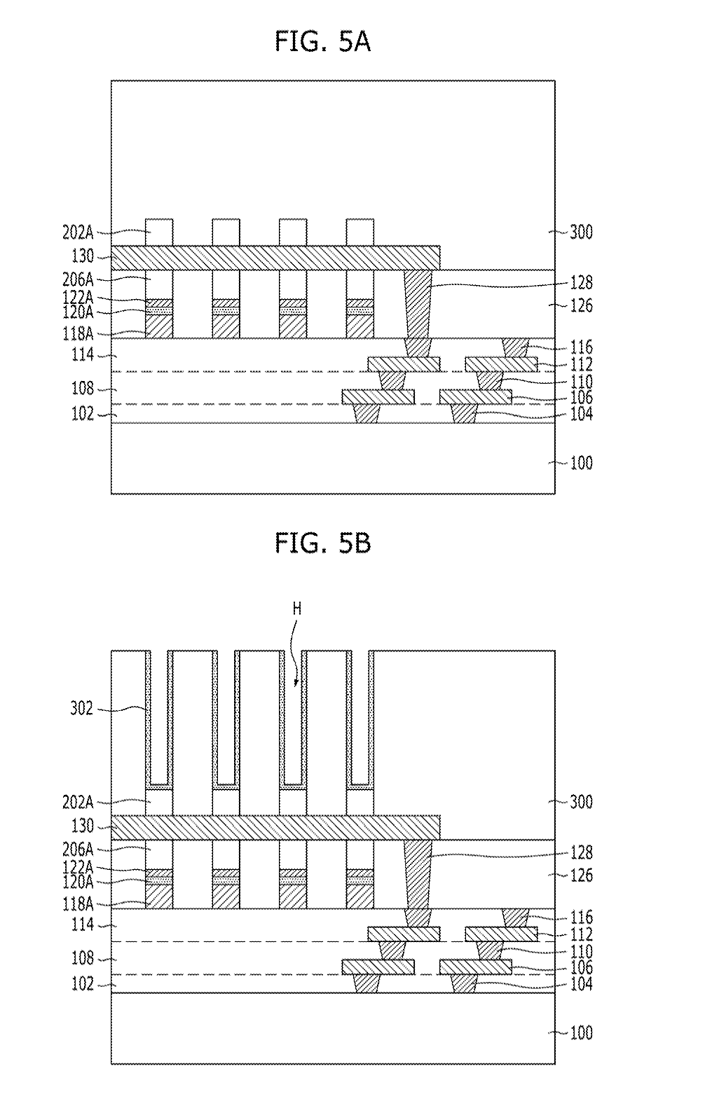

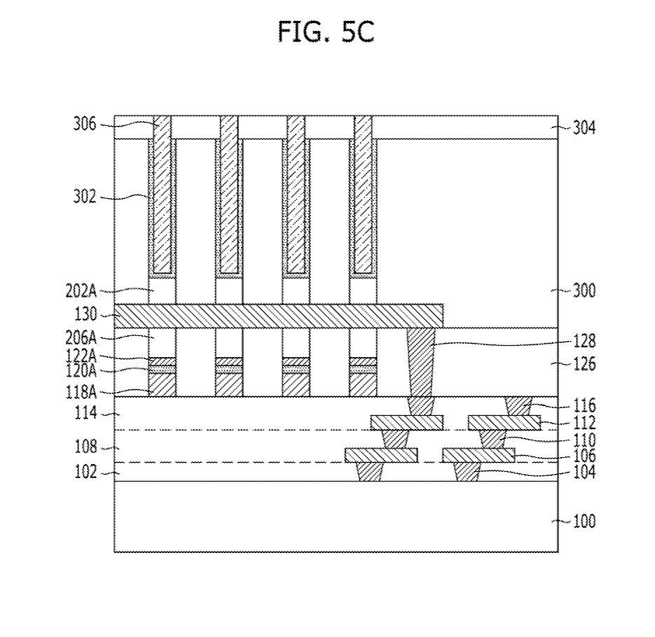

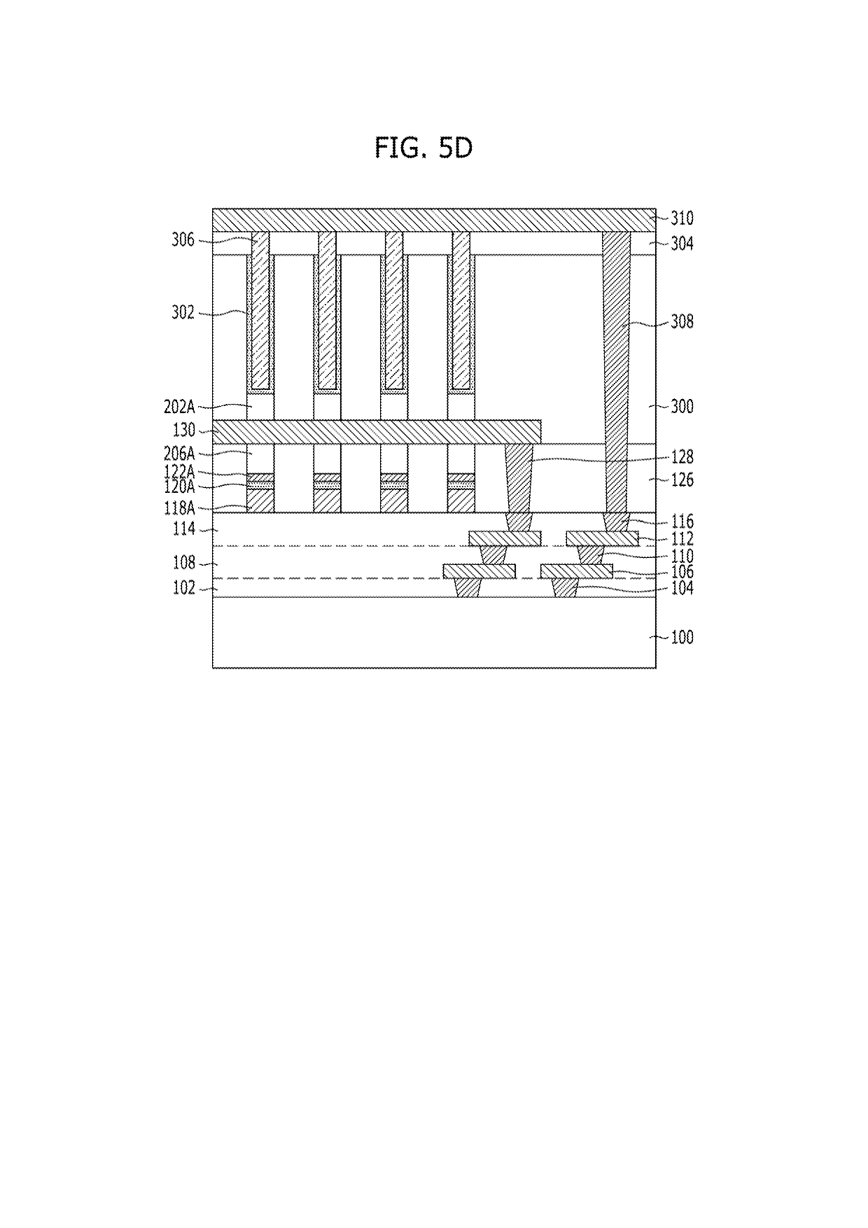

FIGS. 5A to 5D are cross-sectional views illustrating a semiconductor device and a method of manufacturing the same in accordance with a second embodiment of the present invention. In describing the present embodiment, a detailed description of parts that are substantially the same as those of the first embodiment is omitted. First, like in the first embodiment, the processes of FIGS. 4A to 4G are performed, and a process of FIG. 5A is then performed.

Referring to FIG. 5A, after forming a gate insulating layer (not shown) on the sides of the first and the second impurity layer patterns 202A and 204A, the gate electrode 130 of the above-described cell transistor is formed on the sides of the second impurity layer patterns 204A. The gate electrode 130 may be formed by depositing conductive material, such as doped polysilicon, metal, or metal nitride. The gate electrode 130 may be configured to surround the sides of the second impurity layer patterns 204A, extended in one direction, and connected to the fourth contact plug 128.

After removing the hard mask patterns 124 remaining on the first impurity layer patterns 202A, a fifth interlayer insulating layer 300 configured to cover the first impurity layer patterns 202A is formed. The fifth interlayer insulating layer 300 may be formed by depositing one or more of oxide-series materials, for example, silicon oxide (SiO₂), TEOS, BSG, PSG, FSG, BPSG, and SOG to a thickness that a capacitor to be described later may have sufficient capacitance.

Referring to FIG. 5B, holes H where top surfaces of the first impurity layer patterns 202A are exposed are formed by selectively etching the fifth interlayer insulating layer 300. The lower electrodes 302 of the capacitors are formed on the inner walls of the holes H. Each of the holes H may have a circular or oval shape when viewed from a plane parallel to the first substrate 100. The lower electrode 302 may be formed by depositing conductive material, such as doped polysilicon, metal, or metal nitride in a conformable manner.

Referring to FIG. 5C, a sixth interlayer insulating layer 304 is formed on the space in which the lower electrodes 302 are formed. The lower electrodes 302 are exposed by selectively etching the sixth interlayer insulating layer 304. The sixth interlayer insulating layer 304 may be formed by depositing one or more of oxide-series materials, for example, silicon oxide (SiO₂) TEOS, BSG, PSG, FSG, BPSG, and SOG.

A dielectric film (not shown) is formed on the exposed surfaces of the lower electrodes 302. The upper electrodes 306 of the capacitors are formed on the lower electrodes 302. The dielectric film may be formed by conformably depositing material having a high dielectric constant. Each of the upper electrodes 306 may be formed in a pillar shape by depositing conductive material, such as doped polysilicon, metal, or metal nitride.

Referring to FIG. 5D, a fifth contact plug 308 configured to penetrate the fourth to sixth interlayer insulating layers 126, 300, and 304 and connected to the third contact plugs 116 is formed. The fifth contact plug 308 may be formed by selectively etching the fourth to sixth interlayer insulating layers 126, 300, and 304 in order to form a contact hole (not shown) through which the third contact plug 116 not connected to the fourth contact plug 128 is exposed and filling the contact hole with conductive material, such as doped polysilicon, metal, or metal nitride.

Next, a third line 310 connected to the upper electrodes 306 is formed. The third line 310 may be formed by depositing conductive material, such as doped polysilicon, metal, or metal nitride. Meanwhile, the third line 310 may be extended in one direction and connected to the fifth contact plug 308. The third line 310 may be connected to the line layer through the fifth contact plug 308.

The second embodiment differs from the first embodiment in that a capacitor formed of the lower electrode 302, the upper electrode 306, and the dielectric film interposed therebetween is used as a storage element.

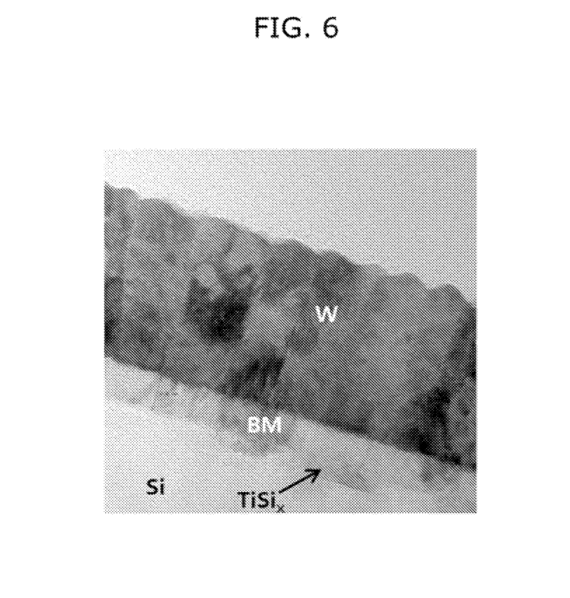

FIG. 6 is an electron microscope photograph illustrating the semiconductor device in accordance with the embodiment of the present invention.

Referring to FIG. 6, titanium silicide (TiSiₓ) may be formed by a reaction of a second metal layer (not shown) with silicon (Si) through an annealing process that is performed when wafer bonding in accordance with the embodiment of the present invention is performed. Titanium silicide (TiSiₓ) may reduce contact resistance. Particularly, from FIG. 6, it can be seen that abnormal silicide is not formed because a barrier layer BM inhibits a reaction of a first metal layer (W) with silicon (Si).

In accordance with the semiconductor devices and the methods of manufacturing the same in accordance with the embodiments of the present invention, abnormal silicidation may be prevented because the barrier layer is formed at the bonding interface of the substrates, and the bonding energy of the substrates may be improved by titanium (Ti)-silicon (Si) bonding.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a line layer formed over a substrate; and
connection structures each configured to comprise a first metal layer pattern, a barrier layer pattern, and a second metal layer pattern sequentially stacked over the line layer, for bonding another substrate to the substrate.

2. The semiconductor device of claim 1, wherein the first metal layer pattern comprises tungsten (W), copper (Cu), gold (Au), or aluminum (Al), or a combination thereof.

3. The semiconductor device of claim 1, wherein the barrier layer pattern comprises metal nitride or nitrided metal silicide, or a combination thereof.

4. The semiconductor device of claim 1, wherein second metal layer pattern comprises titanium.

5. The semiconductor device of claim 1, further comprising:
cell transistors connected to top surfaces of the connection structures; and
storage elements connected to top surfaces of the cell transistors.

6. The semiconductor device of claim 5, wherein:
each of the cell transistors comprises the impurity layer pattern vertically protruded from the substrate, and
the impurity layer pattern comprises silicon.

7. The semiconductor device of claim 5, wherein:
each of the storage elements comprises a lower electrode and an upper electrode separated from the lower electrode, and
a variable resistance layer or a dielectric film is interposed between the lower electrode and the upper electrode.

8. The semiconductor device of claim 7, wherein the variable resistance layer has a structure whose electrical resistance is changed by oxygen vacancies, a migration of ions, a phase change of material.

9. The semiconductor device of claim 7, wherein the variable resistance layer has a magnetic tunnel junction structure whose electrical resistance is changed by a magnetic field or spin transfer torque.

10. The semiconductor device of claim 1, wherein the storage elements are connected to the line layer.

11. A method for manufacturing a semiconductor device, comprising:
forming a line layer over a first substrate;
sequentially stacking a first metal layer, a barrier layer, and a second metal layer over the line layer;
forming one or more impurity layers over a second substrate; and
bonding the first substrate and the second substrate so that the second metal layer and one of the impurity layers face each other.

12. The method of claim 11, wherein the first metal layer comprises tungsten (W), copper (Cu), gold (Au), or aluminum (Al), or a combination thereof.

13. The method of claim 11, wherein the barrier layer comprises metal nitride or nitrided metal suicide, or a combination thereof.

14. The method of claim wherein the second metal layer comprises titanium.

15. The method of claim 11, wherein the impurity layer comprises a plurality of layers in which layers neighboring each other have different conduction types.

16. The method of claim 11, further comprising:
forming impurity layer patterns by selectively etching the impurity layers after bonding the first substrate and the second substrate; and
forming a gate electrode on sides of the impurity layer patterns with a gate insulating layer interposed between the gate electrode and the impurity layer patterns.

17. The method of claim 16, further comprising forming storage elements connected to top surfaces of the respective impurity layer patterns after forming the gate electrode.

18. The method of claim 17, wherein each of the storage elements is formed by sequentially stacking a lower electrode, a variable resistance layer, and an upper electrode.

19. The method of claim 17, wherein forming storage elements connected to top surfaces of the respective impurity layer patterns after forming the gate electrode comprises:
forming an interlayer insulating layer covering the impurity layer patterns;
forming holes through which the respective impurity layer patterns are exposed by selectively etching the interlayer insulating layer;
forming lower electrodes on inner walls of the holes;
forming a dielectric film on a surface of the lower electrodes; and
forming an upper electrode over the respective lower electrodes.

20. The method of claim 17, further comprising forming a line connected to top surfaces of the storage elements after forming the storage elements.
